(19) United States
(12) Patent Application Publication
(10) Pub. No.: US 2010/0214197 A1
(43) Pub. Date: Aug. 26, 2010

(54) CAPACITIVE-LOAD DRIVE DEVICE AND PDP DISPLAY APPARATUS

(76) Inventors: Hiroki MATSUNAGA, Osaka (JP); Tomohiro EBIHARA, Shiga (JP)

Correspondence Address: MCDERMOTT WILL & EMERY LLP, 600 13TH STREET, NW, WASHINGTON, DC, 20005-3096, US

(21) Appl. No.: 12/574,266

(22) Filed: Oct. 6, 2009

(30) Foreign Application Priority Data
Feb. 26, 2009 (JP) 2009-044673

(51) Int. Cl. G09G 3/28; H03K 3/00

(52) U.S. Cl. 345/60; 327/112

(57) ABSTRACT

In a row-electrode drive circuit of a PDP display device, an N-channel MOS low-side transistor of an output section is in an ON state while a light emission of a capacitive load is sustained. Now, if power to a driver section is lost due to, for example, a disconnection of a line from an external power supply to a low-voltage power terminal, this loss of power is detected by a detection section, and a current path via a parasitic diode of a P-channel MOS transistor, which has turned off, in the driver section to the low-voltage power terminal is interrupted. As a result, the N-channel MOS low-side transistor of the output section has the charged electric charge of the capacitive load stored in a parasitic capacity between its drain and gate, so maintains the ON state. Therefore, even when power to the driver section is lost due to, for example, a disconnection of the line while a light emission of the capacitive load is sustained, a case where the low-side transistor of the output section turns off and breaks down is prevented.

### CROSS-REFERENCE TO RELATED APPLICATION

This application claims priority to Japanese Patent Application No. 2009-044673 filed on Feb. 26, 2009, the disclosure of which including the specification, the drawings, and the claims is hereby incorporated by reference in its entirety.

### BACKGROUND

The present invention relates to capacitive-load drive devices, and more specifically relates to improvement of scanning drivers of plasma display panel (hereinafter referred to as PDP) display apparatuses.

Conventionally, a PDP display device controls gas, which is sealed between glass substrates of a PDP panel, by a panel control circuit, and causes a discharge at a predetermined potential between electrodes selected by a column-electrode (also referred to as address-electrode) drive circuit and a row-electrode (also referred to as scan-electrode) drive circuit to produce a light emission. In order to sustain this light emission, two sustain-electrode drive circuits are provided. In particular, the row-electrode drive circuit is a drive circuit for line-by-line progressive scans or interlaced scans in order to select a light emission of an electrode on each row line.

FIG. 5 illustrates a configuration of a main portion of a row-electrode drive circuit included in a conventional PDP display device. In FIG. 5, in the row-electrode drive circuit 29, a P-channel MOS (hereinafter referred to as PMOS) high-side transistor 4, which is connected to a high-voltage power terminal 3, and an N-channel MOS (hereinafter referred to as NMOS) low-side transistor 5 form a push-pull circuit, whose output terminal OUT is connected to a sustain-electrode drive circuit 15 via a capacitive load 10 which represents a PDP panel.

The PMOS high-side transistor 4 is connected via a high-voltage-power-terminal protection diode 25 to a high-voltage power supply 28, while the NMOS low-side transistor 5 is connected to another sustain-electrode drive circuit 35.

In addition, the PMOS high-side transistor 4 is driven by a level shift section 13, and the NMOS low-side transistor 5 is driven by an inverter including a PMOS transistor 7 and an NMOS transistor 8 in a driver section 16. A control circuit section 24 receives a control signal and controls the level shift section 13 as well as the driver section 16.

The control circuit section 24 and the driver section 16 operate by receiving supply of a low voltage VDD via a low-voltage power terminal 1 from an external power supply 14. In addition, a component 17 is a parasitic diode of the PMOS transistor 7, a component 18 is a parasitic diode of the NMOS transistor 8, a component 19 is a parasitic diode of the PMOS high-side transistor 4, and a component 20 is a parasitic diode of the NMOS low-side transistor 5.

Next, the operation of the conventional row-electrode drive circuit will be described. First of all, it is assumed that the NMOS low-side transistor 5 is in an OFF state. That is, it is assumed that the NMOS transistor 8 of the driver section 16 turns on under control of the control circuit section 24, and that the potential of the sustain-electrode drive circuit 35, which is at a low voltage, is transmitted to the gate of the NMOS low-side transistor 5, thereby causing the NMOS low-side transistor 5 to be in an OFF state. In this condition, when a signal is transmitted from the level shift circuit 13 to the gate of the PMOS high-side transistor 4, the PMOS high-side transistor 4 turns on, and a high voltage VDDH of the high-voltage power terminal 3 is transmitted to the capacitive load 10, thereby causing electric charge to be charged in the capacitive load 10 equivalent to a panel capacity.

Thereafter, when the PMOS high-side transistor 4 turns off under control of the level shift circuit 13, now the NMOS transistor 8 of the driver section 16 turns off under control of the control circuit section 24, and the PMOS transistor 7 of the driver section 16 turns on under control of the control circuit section 24. Then, the low voltage VDD of the low-voltage power terminal 1 supplied from the external power supply 14 is transmitted to the gate of the NMOS low-side transistor 5, and the NMOS low-side transistor 5 turns on, thereby causing the charged electric charge stored in the capacitive load 10 to be discharged via the NMOS low-side transistor 5 to the sustain-electrode drive circuit 35, which is at a low voltage. In this way, by charging and discharging the capacitive load 10, the predetermined capacitive load 10 is caused to emit light.

Thus, in order to sustain the light emission after causing the capacitive load 10 to emit light, the above two sustain-electrode drive circuits 15 and 35 are provided. A control operation to sustain a light emission is described below.

One example of a driving operation to sustain a light emission of a predetermined electrode of a PDP panel is described below using FIG. 6. Two electrodes for sustaining a light emission act as the capacitive load 10. During sustaining the light emission as above, in the row-electrode drive circuit 29 of FIG. 5, the PMOS high-side transistor 4 is in an OFF state, and the NMOS low-side transistor 5 is in an ON state.

In this condition for sustaining a light emission, as shown in FIG. 6, the two sustain-electrode drive circuits 15 and 35 each supplies a voltage which alternates between the high potential VDH and the ground potential GND to the capacitive load 10. In this condition, when the potential of one of the sustain-electrode drive circuits (e.g., 15) is at the high potential VDH, the potential of the other sustain-electrode drive circuit (e.g., 35) is changed to the ground potential GND. Thus, the potentials of the both sustain-electrode drive circuits 15 and 35 are configured so that they change in opposite phases to each other, and then charging and discharging of the capacitive load 10 occur repeatedly.

Now, while the NMOS low-side transistor 5 is normally operating in an ON state, if the potential of one sustain-electrode drive circuit 15 changes to the high potential VDH, and the potential of the other sustain-electrode drive circuit 35 changes to the ground potential GND, then the electric charge of the capacitive load 10 flows to ground via the NMOS low-side transistor 5 in an ON state, thereby causing the drain-to-source voltage of the NMOS low-side transistor 5 in an ON state to be a zero voltage. Conversely, when the potential of one sustain-electrode drive circuit 15 changes to the ground potential GND, and the potential of the other sustain-electrode drive circuit 35 changes to the high potential VDH, a current flows into the capacitive load 10 via the parasitic diode 20 between the back gate and the drain of the NMOS low-side transistor 5, thereby causing the drain-to-source voltage of the NMOS low-side transistor 5 to be a zero voltage as well.

A configuration to sustain a light emission of the capacitive load by using two sustain-electrode drive circuits as described above is described, for example, in Japanese Unexamined Patent Application Publication No. 2004-46160.

However, the conventional configuration described above has the following problem.

That is, when a line 1a of the low-voltage power terminal 1 connected to the external power supply 14 is disconnected, or when this line 1a happens to be grounded, the following problem occurs. That is, in this case, since the supply of the low voltage VDD from the low-voltage power terminal 1 to the driver section 16 is interrupted, the low voltage VDD cannot be supplied from the PMOS transistor 7 to the gate of the NMOS low-side transistor 5 in the driver section 16. As a result, the electric charge at the gate of this NMOS low-side transistor 5 flows to ground via the parasitic diode 17 between the drain and the back gate of the PMOS transistor 7 of the driver section 16 or via the control circuit section 24, thereby causing the voltage to drop, and finally drop to the ground potential, and causing the NMOS low-side transistor 5 to switch from an ON state to an OFF state. In a situation where the NMOS low-side transistor 5 has changed to an OFF state as described above, when the potential of the other sustain-electrode drive circuit 35 changes to the high potential VDH (e.g., 240V), the electric charge flows from the output terminal OUT to the capacitive load 10 via the parasitic diode 20 between the back gate and the drain of the NMOS low-side transistor 5 in an OFF state, thereby causing the potential difference between the source and the drain of the NMOS low-side transistor 5 to be a zero voltage. Thereafter, when the potential of the other sustain-electrode drive circuit 35 changes to the ground potential GND, the electric charge which has flowed into the capacitive load 10 (the electric charge of the output terminal OUT) cannot flow to ground by an interception of the NMOS low-side transistor 5 in an OFF state or the parasitic diode 20. Since the potential of the output terminal OUT is maintained at the high potential VDH, the source-to-drain voltage of the NMOS low-side transistor 5 in an OFF state increases instantaneously to the high potential VDH (e.g., 240V) as shown in FIG. 6, and exceeds the breakdown potential of this NMOS low-side transistor 5, thereby causing the output terminal OUT to break down.

### SUMMARY

One objective of the present invention is to provide a capacitive-load drive device which does not cause a breakdown of an output terminal, even when a disconnection of a line of a low-voltage power terminal which supplies a low voltage to a driver section, or a short circuit to ground happens to occur.

In order to meet this objective, the present invention adopts a configuration which, when a disconnection of a line of a low-voltage power terminal which supplies a low voltage to a driver section, or a short circuit to ground occurs, that is, when a low-side transistor connected to a capacitive load switches from an ON state to an OFF state, forcibly maintains the ON state of the low-side transistor.

Specifically, a capacitive-load drive device of the present invention includes an output section in a push-pull configuration which has a high-side transistor receiving power from a first reference potential and a low-side transistor receiving power from a second reference potential changing between at least two levels, and drives a capacitive load, a driver section which sets the low-side transistor of the output section to an ON state based on a third reference potential, and sets the low-side transistor of the output section to an OFF state based on the second reference potential, a control circuit section which controls the high-side transistor of the output section and the driver section, and a detection section which detects that power from the third reference potential to the driver section has been lost, and maintains the ON state of the low-side transistor of the output section.

In one aspect of the capacitive-load drive device of the present invention, the driver section includes a P-channel transistor connected to a gate of the low-side transistor of the output section, and the P-channel transistor is set to an ON state by the control circuit section, applies the third reference potential to the gate of the low-side transistor of the output section, and sets the low-side transistor to an ON state.

In one aspect of the capacitive-load drive device of the present invention, the driver section includes an inverter which has the P-channel transistor and an N-channel transistor connected to the gate of the low-side transistor of the output section.

In one aspect of the capacitive-load drive device of the present invention, the detection section includes a detection transistor which receives power from the third reference potential, and which turns off when the power is lost.

In one aspect of the capacitive-load drive device of the present invention, the detection transistor of the detection section is placed on a current path of a line via a parasitic diode between a drain and a back gate of the P-channel transistor of the driver section to the third reference potential.

In one aspect of the capacitive-load drive device of the present invention, the detection transistor of the detection section includes an N-channel transistor, whose back gate is connected to the second reference potential, whose gate and drain are connected to the third reference potential, and whose source is connected to a back gate of the P-channel transistor of the driver section.

In one aspect of the capacitive-load drive device of the present invention, the detection transistor of the detection section includes a P-channel transistor, whose gate is connected to the second reference potential, whose drain is connected to the third reference potential, and whose source and back gate are connected to a back gate of the P-channel transistor of the driver section.

A PDP display device of the present invention includes the capacitive-load drive device as a row-electrode drive circuit which drives electrodes aligned in a row direction of a plasma display panel as the capacitive load, a column-electrode drive device which drives electrodes aligned in a column direction of the plasma display panel, and two sustain-electrode drive circuits which sustain a light emission of each electrode of the plasma display panel.

In one aspect of the PDP display device of the present invention, one of the two sustain-electrode drive circuits is connected to one electrode of the capacitive load, and the other of the sustain-electrode drive circuits is connected to the other electrode of the capacitive load via the low-side transistor of the output section of the capacitive-load drive device.

In one aspect of the PDP display device of the present invention, the two sustain-electrode drive circuits repeat applying voltages in opposite phases to each other to one or more electrodes which sustain the light emissions.

In one aspect of the PDP display device of the present invention, the other of the sustain-electrode drive circuits changes repeatedly the second reference potential between at least two levels alternately during sustaining the light emissions of one or more predetermined electrodes.

Accordingly, in the present invention, while the driver section sets a low-side transistor of an output section to an ON state based on a third reference potential, if a supply of the third reference potential to the driver section is interrupted due to a line disconnection, etc., the low-side transistor of the output section attempts to change to an OFF state. However, a detection section detects a failure of the supply of the third reference potential, and the detection section itself stores, for example, the charged electric charge from the capacitive load in a gate capacity of the low-side transistor, which maintains an ON state of the low-side transistor. Therefore, even in a situation where the supply of the third reference potential is interrupted, the source-to-drain voltage of this low-side transistor in an ON state is maintained at a zero voltage, thereby causing no breakdown of this low-side transistor, or no breakdown of an output terminal.

### BRIEF DESCRIPTION OF THE DRAWINGS

FIG. 1 is a diagram illustrating an overall schematic configuration of a PDP display device.

FIG. 2 is a diagram illustrating an internal block architecture of a row-electrode drive circuit in accordance with the first embodiment of the present invention.

FIG. 3 is a diagram illustrating a detailed circuit configuration of the same row-electrode drive circuit.

FIG. 4 is a diagram illustrating a detailed circuit configuration of a row-electrode drive circuit in accordance with the second embodiment of the present invention.

FIG. 5 is a diagram illustrating an internal circuit configuration of a conventional row-electrode drive circuit.

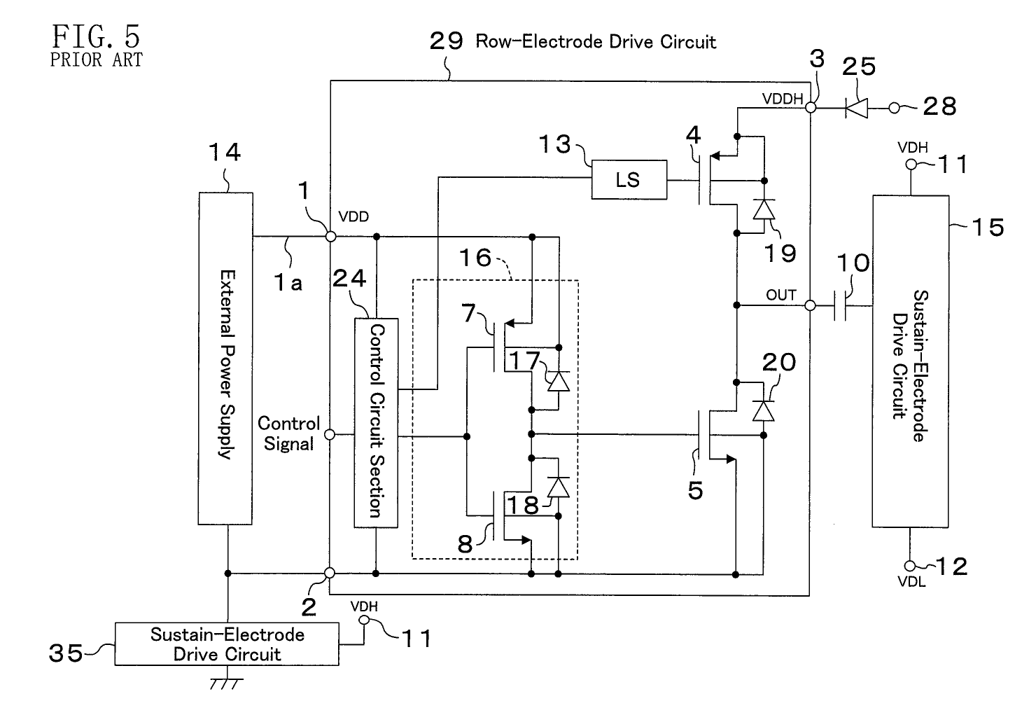

FIG. 6 is a timing diagram illustrating an operation of the same conventional row-electrode drive circuit.

### DETAILED DESCRIPTION

Example embodiments of the present invention is described below with reference to the drawings.

### First Embodiment

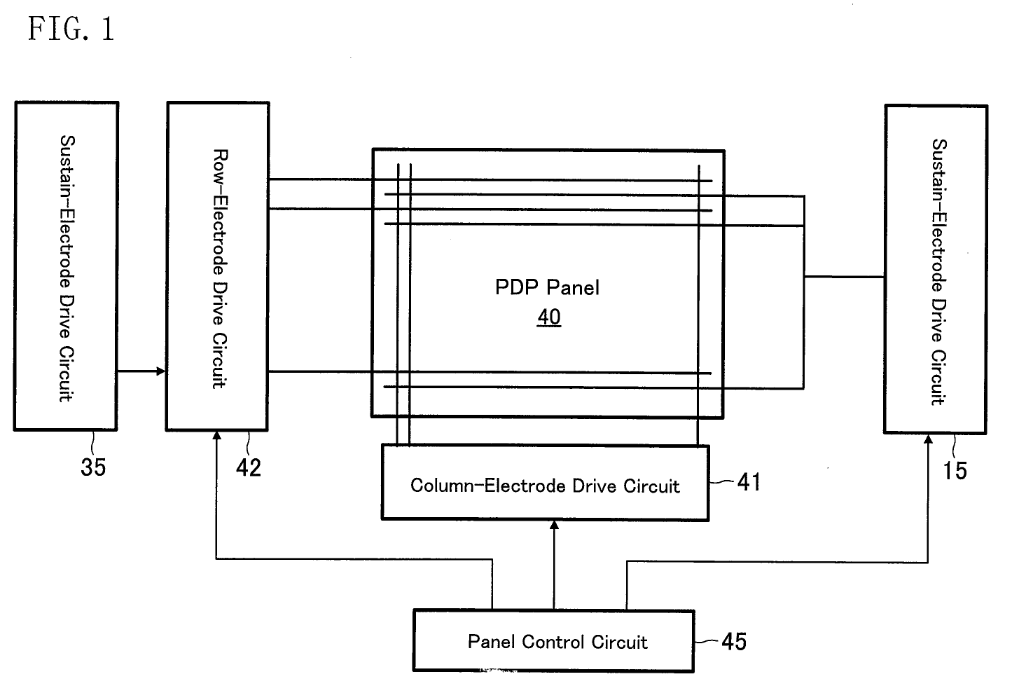

FIG. 1 shows a configuration of a main portion of a PDP display device. In this figure, a component 40 is a PDP panel in which gas is sealed between glass substrates; a component 41 is a column-electrode drive circuit which selects and drives a plurality of electrodes arranged in a column direction; a component 42 is a row-electrode drive circuit which selects and drives a plurality (e.g., 2160) of electrodes arranged in a row direction; a component 15 is a sustain-electrode drive circuit which drives a plurality (e.g., 2160) of electrodes arranged alternately with the plurality of electrodes arranged in a row direction; a component 35 is another sustain-electrode drive circuit which, used with the sustain-electrode drive circuit 15, sustains a light emission of a light emission electrode allocated by the column-electrode drive circuit 41 and the row-electrode drive circuit 42; and a component 45 is a panel control circuit which controls the operation of the four drive circuits.

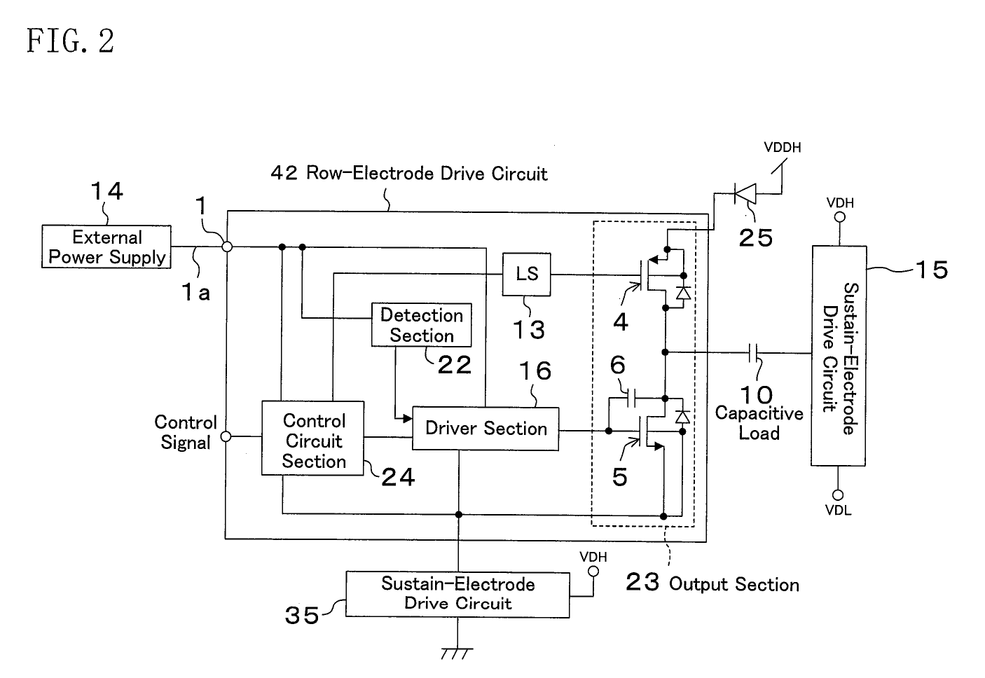

An internal block architecture of the row-electrode drive circuit 42 is shown in FIG. 2. In this figure, the row-electrode drive circuit 42 includes an output section 23 in a push-pull configuration having an inverter in which a PMOS high-side transistor 4 and an NMOS low-side transistor 5 are connected. An output terminal of the inverter is connected to one electrode of a capacitive load 10, which is a PDP panel, and the other electrode of the capacitive load 10 is connected to the sustain-electrode drive circuit 15 to sustain a light emission. The PMOS high-side transistor 4 of the output section 23 receives power from a first reference potential VDDH, and the NMOS low-side transistor 5 is connected to the other sustain-electrode drive circuit 35 which sustains a light emission of an electrode.

In addition, the row-electrode drive circuit 42 includes a level shift section 13 which sets the PMOS high-side transistor 4 of the output section 23 to an ON/OFF state, a driver section 16 which sets the NMOS low-side transistor 5 of the output section 23 to an ON/OFF state, a control circuit section 24 which controls the level shift section 13 and the driver section 16 in response to a control signal. The driver section 16 and control circuit section 24 are both connected to an external power supply 14 of a low voltage VDD via a low-voltage power terminal 1 and a line 1a, and operates with this low voltage VDD as a power source.

Moreover, as a unique architecture to the present invention, the row-electrode drive circuit 42 includes a detection section 22. To the detection section 22, the low voltage VDD of the external power supply 14 is supplied via the line 1a and the low-voltage power terminal 1, and detects that the supply of the low voltage VDD has been lost, as will be described below.

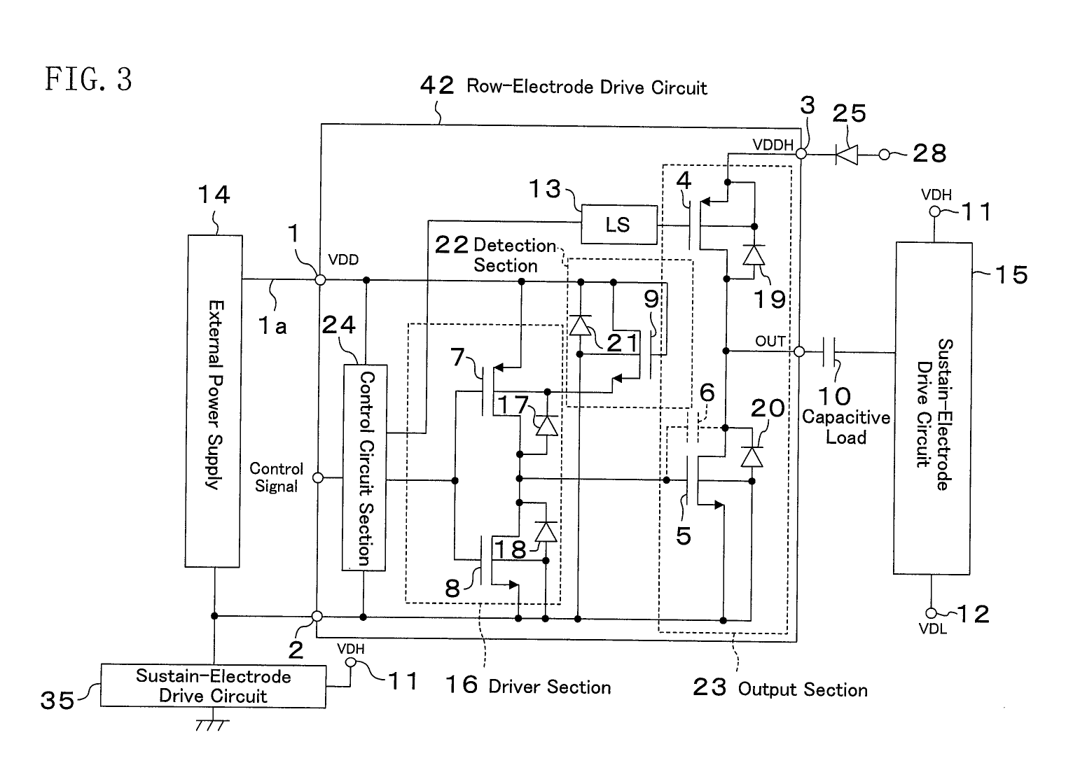

Next, a detailed circuit configuration of the inside of the row-electrode drive circuit 42 is described below based on FIG. 3. As for the row-electrode drive circuit 42 of this figure, in the output section 23, the PMOS high-side transistor 4 has its source connected to the cathode of a high-voltage-power-terminal protection diode 25 and to the cathode of a parasitic diode 19, its drain connected to the capacitive load 10 and to the anode of the parasitic diode 19, and its gate connected to the level shift section 13. The high-voltage-power-terminal protection diode 25 has its anode connected from a high-voltage power terminal 3, which is a high potential (a first reference potential) VDDH, to a high-voltage power supply 28 for the row-electrode drive circuit 42. The high-voltage-power-terminal protection diode 25 has a function to prevent a current which flows into the high-voltage power terminal 3. In addition, the NMOS low-side transistor 5 has its source connected to the sustain-electrode drive circuit 35 and to the anode of a parasitic diode 20, and its drain connected to the cathode of the parasitic diode 20 and to the drain of the PMOS high-side transistor 4. Between the gate and the drain of the NMOS low-side transistor 5 is formed a parasitic capacitance 6.

Moreover, the driver section 16 has an inverter configuration in which a PMOS transistor 7 and an NMOS transistor 8 are connected. The PMOS transistor 7 has its source connected to the low-voltage power terminal 1, its drain connected to the anode of a parasitic diode 17, and its back gate connected to the cathode of the parasitic diode 17. Meanwhile, the NMOS transistor 8 has its source connected to the sustain-electrode drive circuit 35 and to the anode of a parasitic diode 18, and its drain connected to the cathode of the parasitic diode 18. Furthermore, an output point of the driver section 16 (a connection point between the drain of the PMOS transistor 7 and the drain of the NMOS transistor 8) is connected to the gate of the NMOS low-side transistor 5 of the output section 23.

In addition, the detection section 22 includes an NMOS detection transistor 9. The NMOS detection transistor 9 has its source connected to the back gate of the PMOS transistor 7 of the driver section 16 and to the cathode of the parasitic diode 17, its gate and drain connected to the low-voltage power terminal 1, and its back gate connected to the sustain-electrode drive circuit 35. As for the NMOS detection transistor 9, a parasitic diode 21 is formed between the low-voltage power terminal 1 and its back gate.

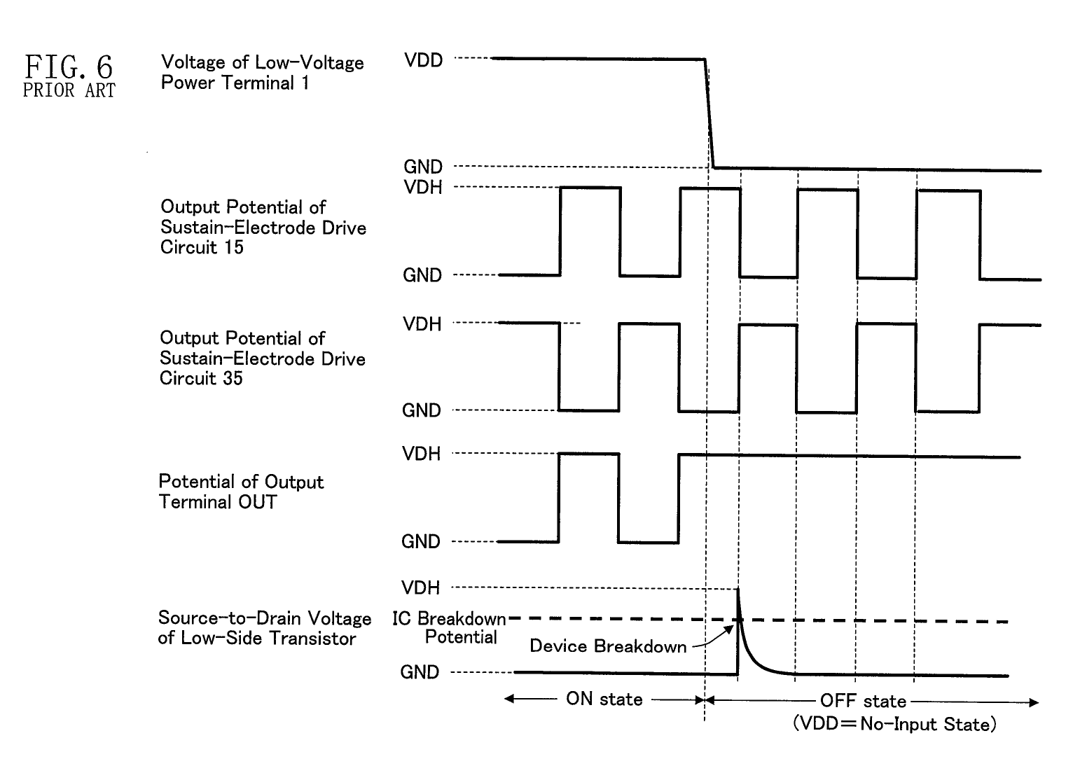

The one of the sustain-electrode drive circuits 15 is connected to a second reference potential, which changes between at least two levels, that is, a power terminal 11 of a high voltage (e.g., 240V) VDH and a power terminal 12 of a low voltage (e.g., 0V) VDL. Similarly, the other of the sustain-electrode drive circuits 35 is connected to the power terminal 11 of the high voltage (e.g., 240V) VDH, and is also grounded. After a capacitive load 10 to produce a light emission is determined, that is, in a situation where the PMOS high-side transistor 4 of the output section 23 is in an OFF state and the NMOS low-side transistor 5 is in an ON state, these two sustain-electrode drive circuits 15 and 35 apply alternately the high voltage VDH and the low voltage VDL (=0V) in opposite phases to each other, as shown in FIG. 6.

As for the capacitive-load drive device of this embodiment configured as above, its operation is described below.

Since, in a normal operation to sustain a light emission of the capacitive load 10, the NMOS low-side transistor 5 is in an ON state, and the operation is similar to one described for the conventional example, its description is omitted.

On the other hand, in an unusual case where, during a normal operation to sustain a light emission of the capacitive load 10, the voltage of the low-voltage power terminal 1 drops to a zero voltage due to a condition where the line 1a which connects the external power supply 14 and the low-voltage power terminal 1 is disconnected, or a short circuit to ground occurs, the PMOS transistor 7 turns off in the driver section 16 (even though the parasitic diode 17 between its drain and back gate exits), then the gate voltage of the NMOS detection transistor 9 of the detection section 22 decreases, thereby causing the NMOS detection transistor 9 to turn off. Then, it is detected that supply of the low voltage (a third reference potential) VDD from the low-voltage power terminal 1 to the driver section 16 has been lost. At this moment of detection, the current path from the back gate of the PMOS transistor 7 of the driver section 16 to the low-voltage power terminal 1 is interrupted by the turnoff behavior of the NMOS detection transistor 9, and the current path from the gate of the NMOS low-side transistor 5 to the low-voltage power terminal 1 is interrupted. As a result, the charged electric charge of the capacitive load 10 is stored in the parasitic capacitance 6 between the gate and the drain of the NMOS low-side transistor 5, thereby causing the gate potential of the NMOS low-side transistor 5 to increase, and the NMOS low-side transistor 5 to be maintained in an ON state.

As a result, when the potential of the sustain-electrode drive circuit 35 changes to the high voltage VDH (e.g., 240V), its electric charge is charged in one electrode of the capacitive load 10 via the parasitic diode 20 of the NMOS low-side transistor 5 of the output section 23 and the output terminal OUT. However, thereafter, when the potential of the sustain-electrode drive circuit 35 changes to the low voltage VDL (e.g., a zero potential), since the NMOS low-side transistor 5 maintains the ON state, a current path through which the charged electric charge of the capacitive load 10 flows out to ground via the NMOS low-side transistor 5 is assured. Therefore, even when the line 1a of the low-voltage power terminal 1 is disconnected or a short circuit to ground occurs, the source-to-drain voltage of the NMOS low-side transistor 5 remains a zero potential, which prevents its breakdown, and a breakdown of the output terminal OUT.

### Second Embodiment

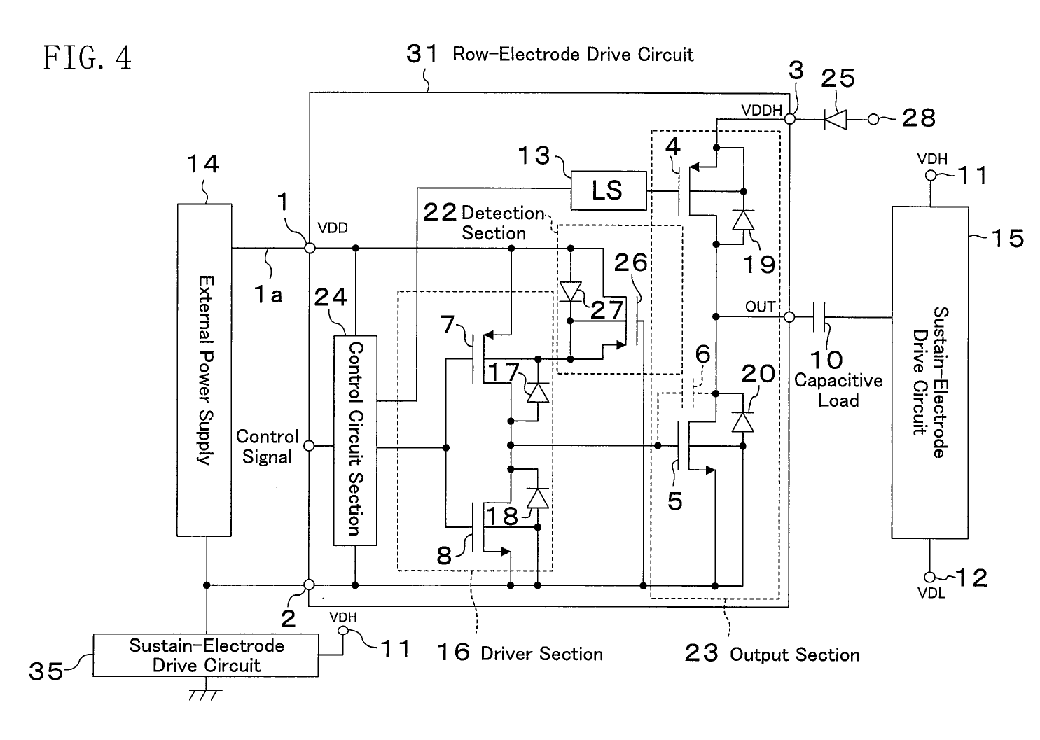

Next, the second embodiment of the present invention is described below based on FIG. 4.

While, in the first embodiment, the detection section 22 is configured with the NMOS detection transistor 9, in this embodiment, the detection section 22 is configured with a PMOS detection transistor 26.

That is, in a row-electrode drive circuit 31 of this embodiment, the detection section 22 includes the PMOS detection transistor 26. This PMOS detection transistor 26 has its source and back gate connected to the back gate of the PMOS transistor 7 of the driver section 16 and to the cathode of the parasitic diode 17, its drain connected to the low-voltage power terminal 1, and its gate connected to the sustain-electrode drive circuit 35. As for this PMOS detection transistor 26, a parasitic diode 27 is formed between its drain and back gate.

Therefore, in this embodiment, although the NMOS low-side transistor 5 of the output section 23 is in an ON state during a normal operation to sustain a light emission of the capacitive load 10, in this condition, and in an unusual case where the voltage of the low-voltage power terminal 1 drops to a zero voltage due to a condition where the line 1a which connects the external power supply 14 and the low-voltage power terminal 1 is disconnected, or a short circuit to ground occurs, the PMOS transistor 7 turns off in the driver section 16 (even though the parasitic diode 17 between its drain and back gate exits). Then, when the drain voltage of the PMOS detection transistor 26 of the detection section 22 decreases, and the gate voltage of the PMOS detection transistor 26 changes to the ground voltage of the sustain-electrode drive circuit 35, the PMOS detection transistor 26 switches from an ON state to an OFF state. Then, it is detected that supply of the low voltage VDD from the low-voltage power terminal 1 to the driver section 16 has been lost. At this moment of detection, the current path from the back gate of the PMOS transistor 7 of the driver section 16 to the low-voltage power terminal 1 is interrupted by the turnoff behavior of the PMOS detection transistor 26, and the current path from the gate of the NMOS low-side transistor 5 to the low-voltage power terminal 1 is interrupted. As a result, the charged electric charge of the capacitive load 10 is stored in the parasitic capacitance 6 between the gate and the drain of the NMOS low-side transistor 5, thereby causing the gate potential of the NMOS low-side transistor 5 to increase, and the NMOS low-side transistor 5 to be maintained in an ON state.

As a result, as with the case of the first embodiment, when the potential of the sustain-electrode drive circuit 35 changes to the high voltage VDH (e.g., 240V), its electric charge is charged in one electrode of the capacitive load 10 via the parasitic diode 20 of the NMOS low-side transistor 5 of the output section 23 and the output terminal OUT. However, thereafter, when the potential of the sustain-electrode drive circuit 35 changes to the low voltage VDL (e.g., a zero potential), since the NMOS low-side transistor 5 maintains the ON state, a current path through which the charged electric charge of the capacitive load 10 flows out to ground via the NMOS low-side transistor 5 is assured. Therefore, even when the line 1a of the low-voltage power terminal 1 is disconnected or a short circuit to ground occurs, a breakdown of the NMOS low-side transistor 5 does not occur, then a breakdown of the output terminal OUT does not occur.

Note that, although the transistors are configured with MOS transistors in the first and the second embodiments, it is needless to say that similar effects can be achieved if the NMOS low-side transistor 5 is replaced with another power device configuration such as an IGBT.

Also, although the present invention is applied to a row-electrode drive circuit of a PDP display device in the first and the second embodiments, it is needless to say that it can be also applied to another capacitive-load drive device in a similar way.

What is claimed is:

1. A capacitive-load drive device comprising:
an output section in a push-pull configuration, having a high-side transistor which receives power from a first reference potential and a low-side transistor which receives power from a second reference potential changing between at least two levels, configured to drive a capacitive load;
a driver section configured to set the low-side transistor of the output section to an ON state based on a third reference potential, and to set the low-side transistor of the output section to an OFF state based on the second reference potential;
a control circuit section configured to control the high-side transistor of the output section and the driver section; and
a detection section configured to detect that power from the third reference potential to the driver section has been lost, and to maintain the ON state of the low-side transistor of the output section.

2. The capacitive-load drive device of claim 1, wherein
the driver section includes a P-channel transistor connected to a gate of the low-side transistor of the output section, and
the P-channel transistor is set to an ON state by the control circuit section, applies the third reference potential to the gate of the low-side transistor of the output section, and sets the low-side transistor to an ON state.

3. The capacitive-load drive device of claim 2, wherein
the driver section includes an inverter which has the P-channel transistor and an N-channel transistor connected to the gate of the low-side transistor of the output section.

4. The capacitive-load drive device of claim 2, wherein
the detection section includes a detection transistor which receives power from the third reference potential, and which turns off when the power is lost.

5. The capacitive-load drive device of claim 4, wherein
the detection transistor of the detection section is placed on a current path of a line via a parasitic diode between a drain and a back gate of the P-channel transistor of the driver section to the third reference potential.

6. The capacitive-load drive device of claim 4, wherein
the detection transistor of the detection section includes an N-channel transistor, whose back gate is connected to the second reference potential, whose gate and drain are connected to the third reference potential, and whose source is connected to a back gate of the P-channel transistor of the driver section.

7. The capacitive-load drive device of claim 4, wherein
the detection transistor of the detection section includes a P-channel transistor, whose gate is connected to the second reference potential, whose drain is connected to the third reference potential, and whose source and back gate are connected to a back gate of the P-channel transistor of the driver section.

8. A PDP display apparatus comprising:
the capacitive-load drive device of claim 1 as a row-electrode drive circuit which drives each of the electrodes aligned in a row direction of a plasma display panel as the capacitive load;
a column-electrode drive device configured to drive electrodes aligned in a column direction of the plasma display panel; and
two sustain-electrode drive circuits configured to sustain a light emission of each electrode of the plasma display panel.

9. The PDP display apparatus of claim 8, wherein
one of the two sustain-electrode drive circuits is connected to one electrode of the capacitive load, and
the other of the sustain-electrode drive circuits is connected to the other electrode of the capacitive load via the low-side transistor of the output section of the capacitive-load drive device.

10. The PDP display apparatus of claim 8, wherein
the two sustain-electrode drive circuits repeat applying voltages in opposite phases to each other to one or more electrodes which sustain the light emissions.

11. The PDP display apparatus of claim 9, wherein
the other of the sustain-electrode drive circuits changes repeatedly the second reference potential between at least two levels alternately during sustaining the light emissions of one or more predetermined electrodes.
